(19) United States
(12) Patent Application Publication
(10) Pub. No.: US 2021/0229172 A1
(43) Pub. Date: Jul. 29, 2021

(54) ELECTRICALLY CONDUCTIVE PASTE FOR FORMING PILLARS

(71) Applicant: DIC Corporation, Tokyo (JP)

(72) Inventors: Ryota Yamaguchi, Sakura-shi (JP); Nobuhiro Sekine, Sakura-shi (JP); Makoto Yada, Sakura-shi (JP); Yoshiyuki Sano, Sakura-shi (JP)

(73) Assignee: DIC Corporation, Tokyo (JP)

(21) Appl. No.: 15/733,948

(22) PCT Filed: Apr. 25, 2019
(86) PCT No.: PCT/JP2019/017602

§ 371 Date: Dec. 1, 2020

(30) Foreign Application Priority Data
Jun. 27, 2018 (JP) 2018-121936

(51) Int. Cl. B22F 1/02; H01L 23/00; H01B 1/22; B22F 9/24

(52) U.S. Cl. CPC B22F 1/02; H01L 24/13; H01B 1/22; B22F 2304/05; H01L 2224/1329; H01L 2224/13339; H01L 2224/13347; B22F 9/24

(57) ABSTRACT

The known electrolytic plating method is disadvantageous in that it is difficult to form thin pillars without being influenced by undercuts. The electroless plating method is disadvantageous in that it is difficult to form pillars in the same shape without voids. As a solution to these, the electrically conductive paste according to the present invention for forming pillars is used to make pillars by filling. This helps prevent undercuts, and it is also intended to provide metal pillars in the same shape with good reproducibility. The inventors found that an electrically conductive paste that is very small fine metal particles and contains a particular percentage of fine metal particles is extraordinarily advantageous in forming pillars.

### TECHNICAL FIELD

The present invention relates to an electrically conductive paste that contains fine metal particles for metal pillars or metal posts. Metal pillars and metal posts are terminals for flip-chip mounting, a method for coupling a semiconductor chip and a package interposer together in a semiconductor package.

### BACKGROUND ART

Semiconductor devices are formed by creating electronic circuits on semiconductor chips and coupling electrodes on the semiconductor chips and those on a semiconductor package together. Previously, the electrical coupling between electrodes on semiconductor chips and those on a semiconductor package was accomplished using gold or copper bonding wires. The method for electrical coupling between the semiconductor chips and semiconductor package now is flip chip. A typical method for coupling in the flip-chip technique is by using gold or solder bumps.

Against the background of increasing density of chips in recent years, however, flip chip using copper pillars is in focus today. The copper pillars are formed on the semiconductor chips and connected to electrodes on the semiconductor package at their tip. A commonly used type of copper pillar is ones having a diameter of 70 μm or less and a height of 50 to 60 μm.

Made of the low-electrical-resistance material of copper, copper pillars allow the flow of high electric currents compared with solder bumps. The supply of solder, moreover, is smaller for copper pillars than for solder bumps, which means using copper pillars helps achieve a fine bump pitch. Whereas gold bumps touch electrodes in a small area, furthermore, copper pillars can have the same cross-sectional area throughout their length from electrodes on the semiconductor chips to those on the semiconductor package. This also contributes to their advantage of allowing the flow of high electric currents.

For these reasons, the making of copper pillars is important in semiconductor mounting. There is a need for an easy and convenient method for making copper pillars.

A known method for forming copper pillars on a substrate is by using plating technology.

This is a method in which a plating layer called a seed layer is made on electrode pads, and the copper pillars are formed by electrolytic plating. Forming the pillars by plating, however, involves a step of removing a patterned resist layer and the seed layer after making the pillars because the seed layer is formed over the entire surface of the substrate. A problem is that because of undercuts that occur in the step of removing the seed layer by etching, it is difficult to make thin pillars by plating.

Another method for forming copper pillars by plating technology is the use of electroless plating. This is a method in which a photoresist layer is formed on semiconductor chips, openings are created in the portions of the photoresist layer in which the copper pillars are to be formed, copper plating is formed in the openings by electroless plating, and then solder plating is formed on the top of the copper plating. However, if one tries in this method to form thin and long copper pillars, or to achieve a large height/diameter ratio (aspect ratio) of the copper pillars, they need to grow solder in deep and small-diameter holes. A problem in this case is quality and reproducibility issues caused by, for example, poor throughput due to difficulty in continuous delivery of a sufficiently thick plating solution to the openings and consequent slow growth of plating, shape uncertainties such as a diameter of the copper pillars smaller than intended, and voids in the built-up layer of copper.

Plating, furthermore, involves recycling or disposing of large amounts of waste liquids. The enormous burdens it places on the environment and the cost involved in facility maintenance have led to a desire for an alternative.

### CITATION LIST

### Patent Literature

PTL 1: Japanese Unexamined Patent Application Publication No. 2011-29636

PTL 2: Japanese Unexamined Patent Application Publication No. 2012-15396

PTL 3: WO 2016/031989

### SUMMARY OF INVENTION

### Technical Problem

Overall, the known electrolytic plating method is disadvantageous in that it is difficult to form thin pillars without being influenced by undercuts.

The electroless plating method, on the other hand, is disadvantageous in that it is difficult to form pillars in the same shape without voids.

Making pillars by filling using the electrically conductive paste according to the present invention for forming pillars helps prevent undercuts. It is also intended to provide metal pillars in the same shape with good reproducibility.

### Solution to Problem

After extensive research to solve the above problems, the inventors found that an electrically conductive paste that is exceedingly small fine metal particles and contains a particular percentage of fine metal particles is extraordinarily advantageous in forming pillars.

That is, the present invention provides:

(1) The present invention is an electrically conductive paste for forming pillars, the paste containing fine metal particles and a protective agent, wherein a diameter of the fine metal particles is less than 1 μm, and a percentage of the fine metal particles in the electrically conductive paste is 40% or more and less than 95% concentration by mass;

(2) Is the electrically conductive paste according to (1) for forming pillars, the paste further containing a solvent having a boiling point of 250° C. or less; and

(3) Is the electrically conductive paste according to (1) or (2) for forming pillars, wherein the protective agent as in the above contains an organic compound including a C8 to C200 polyethylene oxide structure;

(4) The electrically conductive paste according to any of (1) to (3) for forming pillars, wherein a percentage of the organic compound as in the above including a C8 to C200 polyethylene oxide structure is 15% concentration by mass or less of the entire paste;

(5) The electrically conductive paste according to any of (1) to (4) for forming pillars, wherein the fine metal particles as in the above are particles of silver, copper, or a composite thereof; and

(6) A pillar made using the electrically conductive paste according to any of (1) to (5) for forming pillars.

### Advantageous Effects of Invention

The present invention is an electrically conductive paste for forming pillars by filling.

By using the present invention, manufacturers can form pillars with ease and convenience. The pillars are formed without using the known plating technology, but instead by preliminarily spreading the electrically conductive paste to fill openings in a patterned resist layer, for example using a squeegee.

Direct formation of pillars on an electrode substrate using an electrically conductive paste helps eliminate undercuts during etching, which have been a problem with the known process. Copper pillars can therefore be formed thin.

Pillar making using an electrically conductive paste is free of limitations such as degradation of the plating solution and rate control by the diffusion of ions. The inventors, therefore, believe it can solve even the quality and reproducibility issues encountered when electroless plating is used.

### BRIEF DESCRIPTION OF DRAWINGS

FIG. 1 is a surface geometry after an electrically conductive paste was spread to fill openings having a diameter of 30 μm and sintered.

FIG. 2 is a cross-sectional profile after an electrically conductive paste was spread to fill openings having a diameter of 30 μm and sintered.

### DESCRIPTION OF EMBODIMENTS

The following describes the present invention in detail.

### <Fine Metal Particles>

Any metal species can be used as fine metal particles according to the present invention, provided the metal species chemically binds with a functional group in the protective agent described below. For example, metals such as gold, silver, copper, nickel, zinc, aluminum, platinum, palladium, tin, chromium, lead, and tungsten can be used. One metal species, a mixture of two or more, or an alloy may be used.

As for the percentage of the fine metal particles in the electrically conductive paste, the particles can be used in the range of 40% or more and less than 95% concentration by mass. More preferably, the particles can be used in the range of 60% to 90% concentration by mass.

### <Protective Agent>

The protective agent according to the present invention can be any compound that has a functional group compatible with the fine metal particles and the solvent. A protective agent can be used whatever its molecular weight is. High electrical conductivity and dispersion stability can be given to the fine metal particles by designing the protective agent according to the metal species used and the desired characteristics.

Specifically, high dispersion stability can be added to the fine particles by using a protective agent having a group that has a relatively high potential to adsorb to metals. Examples include the carboxy, phosphoric acid, sulfonic acid, and heteroaromatic (e.g., imidazole) groups. An electrical conductivity high enough that, the volume resistivity will be low even with low-temperature sintering can be added by using a protective agent having a group that interacts moderately with metals and has varying degrees of adsorption potential according to the acidity/basicity of the medium in which it is dispersed. Examples include the amino (e.g., dimethylaminoethyl and dimethylaminopropyl), hydroxy (hydrozyethyl and hydroxypropyl), and aromatic (e.g., benzyl) groups. In this way, the characteristics of the fine metal particles can be changed flexibly by selecting the protective agent for the fine metal particles according to purposes. If a low-molecular-weight protective agent is used, various characteristics can be achieved by using two or more compounds in combination. If a high-molecular-weight protective agent is used, various characteristics can be achieved by changing the number and type of functional groups in the compound.

As for the concentration of the protective agent in the electrically conductive paste, the protective agent can be used in the range of 15% concentration by mass or less of the entire paste. More preferably, the protective agent concentration is in the range of 10% concentration by mass or less. Too high a concentration of the protective agent will cause insufficient formation of necks between the metal particles when sintered, making it difficult to give the particles high electrical conductivity.

Specific examples of protective agents include, for example, the following substances. For instance, examples of carboxylic acids, which have a carboxyl group, include formic acid, acetic acid, formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, behenic acid, oleic acid, palmitoleic acid, eicosenoic acid, erucic acid, nervonic acid, ricinoleic acid, oxalic acid, malonic acid, succinic acid, glutaric acid, adipic acid, pimelic acid, suberic acid, azelaic acid, sebacic acid, diglycolic acid, maleie acid, itaconic acid, benzoic acid, N-oieylsarcosine, N-carbobenzoxy-4-aminobutyric acid, p-coumaric acid, 3-(4-hydroxyphenyl)propionic acid, 3-hydroxyrayristic acid, 2-hydroxypalmitic acid, 2-hydroxyicosanoic acid, 2-hydroxydocosanoic acid, 2-hydroxvtricosanoic acid, 2-hydroxytetracosanoic acid, 3-hydroxycaproic acid, 3-hydroxyoctanoic acid, 3-hydroxynonanoic acid, 3-hydroxydecanoic acid, 3-hvdroxyundecanoic acid, 3-hydroxydodecanoic acid, 3-hydroxytridecanoic acid, 3-hydroxytetradecanoic acid, 3-hydroxyhexadecanoic acid, 3-hydroxyheptadecanoic acid, 3-hydroxyoctadecanoic acid, 15-hydroxypentadecanoic acid, 17-hydroxyheptadecanoic acid, 15-hydroxypentadecanoic acid, 17-hydroxyheptadecanoic acid, lauroylsarcosine, 6-aminohexanoic acid, 2-benzoylbenzoic acid, 12-hydroxystearic acid, 12-hydroxypentadecanoic acid, 2-hydroxypalmitic acid, 3-hydroxydecanoic acid, 15-hydroxypentadecanoic acid, lauroylsarcosine, 6-aminohexanoic acid, N-(tert-butoxycarbonyl)-6-aminohexanoic acid, [2-(2-methoxyethoxy)ethoxy]acetic acid, and N-carbobenzoxy-β-alanine. Compounds that form multimers can be used as dimers or multimers from trimers to hexamers thereof. One carboxylic acid or a combination of two or more in any proportions can be used.

To take another example, examples of amines, which have an amino group, include 2-methoxyethylamine, 2-ethoxyethylamine, 2-isopropoxyethylamine, 3-methoxypropylamine, 3-ethoxypropylamine, 3-isopropoxypropylamine, 3-(2-ethylhexyloxy)propylamine, N-methylethylenediamine, N-ethylethylenediamine, N-isopropylethylenediamine, N-methyl-1,3-propanediamine, 3-isopropylaminopropylamine, N,N-dimethylethylenediamine, N,N-diethylethylenediamine, N,N-dimethyl-1,3-propansdiamine, N,N-diethyl-1,3-propanediamine, N-(3-aminopropyl)morpholine, N-(tert-butoxycarbonyl)-1,4-diaminobutane, N-(tert-butoxycarbonyl)-1,5-diaminopentane, N-(tert-butoxycarbonyl)-1,6-diaminohexane, 2-(aminoethylamino)ethanol, 2-(arainoethoxy)ethanol, 3-(2-hydroxyethylaramino)propylamine, N-(2-hydroxypropyl)ethylenediamine, and N-(3-aminopropyl)diethanolamine. Besides these, amines that are secondary or tertiary amine compounds can be additionally used.

An example of a protective agent that can be used in the present invention is an organic compound that includes a C8 to C200 polyethylene oxide structure. With its high compatibility with the specific solvents used in the present invention, such as alcohol solvents having a boiling point of 250° C. or less, the polyethylene oxide moiety of such a protective agent provides strong control of the aggregation of the fine metal particles, thereby allowing the fine metal particles to be dispersed well. This means dense packing of the fine metal particles; with such a protective agent, therefore, no voids are created when the protective agent and solvent are decomposed and removed by heating, and dense packing can be achieved.

In addition, fine metal particles synthesized using a protective agent according to the present invention have only a small amount of protective agent, as small as 2% to 10% concentration by mass. The protective agent therefore does not prevent the metal particles from forming necks when fired.

Examples of fine metal particles containing an organic compound that includes a C8 to C200 polyethylene oxide structure (composite of an organic compound and fine metal particles) that can be used in the present invention include Japanese Patent No. 4784847, Japanese Unexamined Patent Application Publication No. 2013-60637, and Japanese Patent No. 5077728 and can be synthesized by the methods described there. Characterized by a thioether (R—S—R′) compound's moderate compatibility with and adsorptivity to and quick elimination upon heating from the surface of the metal particles, these examples are under development as low-temperature fusible fine metal particles.

Other examples include fine metal particles combined with those thioetner-bearing polymeric compounds as in Japanese Unexamined Patent Application Publication No. 2010-209421 that have a C8 to C200 polyethylene oxide moiety, and fine metal particles combined with those thioether- and phosphate-bearing polymeric compounds as in Japanese Patent No. 4697356 that have a C8 to C200 polyethylene oxide moiety. The production of these polymeric compounds having a polyethylene oxide structure can be by the methods described in the respective publications.

In the present invention, such organic compounds of phosphate type having a polyethylene oxide structure have a phosphate group as well as a thioether group. By virtue of having these groups, they add moderate compatibility with and absorptivity to and quick elimination upon heating from the surface of the fine metal particles.

The chain functional group that has an ethylene oxide structure as its repeating unit serves as a solvent-philic moiety. Preferably, this polyethylene oxide structure is one that has 8 to 200 carbon atoms, more preferably one that has 8 to 100 carbon atoms.

### <Solvent>

Any kind of solvent, whatever its molecular weight is, can be used in the present invention as long as it is a compound having a boiling point of 250° C. or less. Water or/and an organic solvent can be used as solvent(s). To produce an electrically conductive paste that has a uniform particle system, it is preferred that the solvent be a good solvent, in which the fine metal particles do not aggregate together.

Desirably, the solvent evaporates when the electrically conductive paste is sintered. High sintering temperatures, however, alter and damage the resist film. It is therefore more desirable that the solvent be an organic solvent having its boiling point in a temperature range within which the resist film is not damaged.

Here is a list of examples of organic solvents that are particularly suitable for use. The present invention, however, is not limited to these compounds.

For instance, examples of hydroxyl-bearing organic solvents include methanol, ethanol, 1-propanol, isopropanol, 1-butanol, isobutanol, sec-butanol, tert-butanol, amyl alcohol, tert-amyl alcohol, 1-hexanol, cyclohexanol, benzyl alcohol, 2-ethyl-1-butanol, 1-heptanol, 1-octanol, 4-methyl-2-pentanol, neopentyl glycol, propionitrile, ethylene glycol, propylene glycol, 1,3-butanediol, 1,4-butanediol, 2,3-butanediol, isobutylene glycol, 2,2-dimethyl-1,3-butanediol, 2-methyl-1,3-pentanediol, 2-methyl-2,4-pentanediol, diethvlene glycol, triethylene glycol, tetmethylene glycol, 1,5-pentanediol, 2,4-pentanediol, dipropylene glycol, 2,5-hexanediol, glycerol, diethylene glycol monobutyl ether, ethylene glycol raonobenzyl ether, ethylene glycol monoethyl ether, ethylene glycol monometnyl ether, ethylene glycol monophenyl ether, propylene glycol dimethyl ether, polyethylene glycol, and polypropylene glycol.

Particularly suitable organic solvents also include other, hydroxyl-free ones, such as acetone, cyclepentanone, cyciohexanone, acetophenone, acrvlonitriie, propionitrile, n-butyronitrile, isobutyronitrile, y-butyroiactone, ε-caprolactone, propiolactone, 2,3-butylene-carbonate, ethylene carbonate, 1,2-ethylene carbonate, dimethyl carbonate, ethylene carbonate, dimethyl malonate, ethyl lactate, methyl benzoate, methyl salicylate, ethylene glycol diacetate, ε-caprolactam, dimethyl sulfoxide, N,N-dimethylformamide, N,N-dimethylacetamide, N-methylformamide, N-methylacetamide, N-ethylacetamide, N,N-diethylfcrmamide, formamide, pyrrolidine, 1-methyl-2-pyrrolidinone, hexamethylphosphoric triamide, and naphthalene.

As for the concentration of the solvent in the electrically conductive paste, the solvent can be used in the range of 60% concentration by mass or less. More preferably, the solvent concentration is in the range of 30% concentration by mass or less.

### (Measurement of the Boiling Point of a Mixture)

If a solvent mixture, i.e., a combination of multiple solvents, is used, the boiling point of the solvent mixture (solution) can be measured following the test method of “equilibrium reflux boiling point” specified in Section 7.1 of JIS K2233-1985 “Non-petroleum base motor vehicle brake fluids.”

A specific example is:

(1) Mix the two solvents together, and put 60 mL of the mixed solution and a stirrer bar into a 100-mL three-neck flask.

(2) Heat the flask in an oil bath, with the surface of the oil flush with that of the solution in the flask.

(3) At the time when bubbles form in the solution, read the temperature inside the flask. Report the reading as the boiling point of the mixed solution.

A boiling point estimated following this specific example can be used as the boiling point of the solvent. If a solvent mixture, i.e., a combination of two or more solvents, is used in the present invention, there is no restriction on it as long as its boiling point is 250° C. or less.

### <Synthesis of the Fine Metal Particles>

Although chemical reduction was used, the synthesis of the fine metal particles in the present can be by any method in which the surface of fine metal particles can be protected from a protective agent and that gives particles having a diameter of 1 μm or less. For example, in the category of wet. processes, thermal decomposition and electrochemical processes can be used besides chemical reduction. Gas evaporation and sputtering, which are dry processes, can also be used.

To explain the advantages of the present invention, the following describes an example of a method for producing fine metal particles in which the protective agent used in the present invention is an organic compound that includes a C8 to C200 polyethylene oxide structure.

The specific example of the production method given below describes a case in which the metal species is copper or silver. This, however, does not mean that the metal species in the electrically conductive paste according to the present invention needs to be copper or silver.

fine metal particles combined with an organic compound including a C8 to C200 polyethylene oxide structure can be easily prepared by combining a step of mixing a cupric or argentous compound in a solvent in the presence of an organic thioether compound with a step of reducing the copper or silver ions.

A cupric compound can be a generally available copper compound; compounds such as sulfates, nitrates, carboxylates, carbonates, chlorides, and acetylacetonate complexes can be used. If the manufacturer wants to obtain a composite with fine particles of zerovalent copper, the starting material for production can be a divalent compound or monovalent compound, with or without water or water of crystallization. Specific examples include CUSO_{4,} Cu(NO3)₂, Cu(OAc)₂, Cu(CH₃CH₂COO)₂, Cu(HCOO)₂, CuCO₃, CUCl₂, CU₂O, and C₅H₇CuO₂, all described without water of crystallization. Basic salts obtained by heating such salts or exposing such salts to a basic atmosphere, such as Cu(OAc)₂.CuO, Cu(OAc)₂.2CuO, and CuCl(OH)₃, are the most suitable for use. Such a basic salt may be prepared in the reaction system, or may be prepared separately, i.e., outside the reaction system, before use. It is also possible to employ the common method of forming a complex with ammonia or an amine compound to ensure solubility and using this complex for reduction.

An argentous compound can be a generally available silver compound. Examples include silver nitrate, silver oxide, silver acetate, silver fluoride, silver acetylacetonate, silver benzoate, silver carbonate, silver citrate, silver hexafluorophosphate, silver lactate, silver nitrite, and silver pentafluoropropionate. In view of ease of handling and industrial availability, it is preferred to use silver nitrate or silver oxide.

Such a cupric or argentous compound is dissolved or mixed in a medium in which an organic thioether compound has been dissolved or dispersed beforehand. For media that can be used here, water, ethanol, acetone, ethylene glycol, diethylene glycol, glycerol, and mixtures thereof are suitable for use, although depending partly on the structure of the organic compound used. A water-ethylene glycol mixture is particularly preferred.

Preferably, the concentration of the organic thioether compound in the medium is adjusted to the range of 0.3% to 10% concentration by mass. This makes it easier to control the subsequent reducing reaction.

Into the prepared medium, the cupric or argentous compound is added at once or in divided portions and mixed in. If the compound is not readily soluble in the medium, the compound may be dissolved in a small amount of a good solvent before addition into the medium.

For the proportions of the organic thioether and cupric or argentous compounds mixed together, it is preferred to select appropriate proportions according to the protective ability of the organic thioether compound in the reaction medium. Usually, the organic thioether compound is prepared in the range of 1 mmol to 30 mmol (approximately 2 to 60 g if a polymer having a molecular weight of 2000 is used), preferably used in the range of 15 to 30 mmol in particular, per mol of the cupric or argentous compound. Here, if an organic phosphate compound having a polyethylene oxide structure is used, too, the same procedure works. The amount of organic compound used per mol of the cupric or argentous compound is also the same as described above.

Then the copper or silver ions are reduced using a reducing agent. Various reducing agents can be used, and compounds with which the reduction of copper or silver can proceed at temperatures from ice-cold temperatures to 80° C. or less are suitable for use as the reducing agent. Such compounds give a composite that forms little precipitate. Examples include hydrazine compounds, hydroxylamine and its derivatives, metal hydrides, phesphinates, aldehydes, enediols, and hydroxy ketones.

If copper ions are reduced, potent reducing agents are suitable. Specific examples include hydrazine hydrate, unsymraetrical dimethylhydrazine, an aqueous solution of hydroxylamine, and sodium borohydride. By virtue of their ability to reduce copper compounds to zero valency, these are suitable if a composite of the organic compound and copper nancparticles is produced by turning cupric and cuprous compounds into reduced copper.

Suitable conditions for the reduction vary with the raw-material cupric compound, the reducing agent, whether complexing is involved or not, the medium, and the organic thioether compound. For example, if copper(II) acetate is reduced in an aqueous system using sodium borohydride, nanoparticles of zerovalent copper can be prepared even at near ice-cold temperatures. If hydrazine is used, however, the reaction is slow at room temperature; the reduction is smooth only when the system is heated to approximately 60° C., and, if copper acetate is reduced in an ethylene glycol/water system, the reaction takes approximately 2 hours to complete at 60° C. When the reaction ends in such a way, a reaction mixture containing a composite of the organic compound and copper-based fine particles is obtained.

Owing to the effect of the protective agent, fine particles of copper prepared in such a way can be dispersed well even if they are made into a dry powder by complete removal of water and then reconstituted with the solvent.

Preparing a liquid mixture of a thioether organic compound, a medium as described above, and a cupric compound with added nano-silver beforehand and then reducing copper ions by adding a reducing agent in the way described above gives silver-core copper-shell fine particles, i.e., nano-silver having its surface coated with copper.

The opposite, i.e., preparing a liquid mixture of a thioether organic compound, a medium as described above, and an argentous compound with added nano-copper beforehand and then reducing silver ions by adding a reducing agent in the way described above, gives copper-core silver-shell fine particles, i.e., nano-copper having its surface coated with silver.

The reduction may optionally be followed by a step of removing, for example, metal compound residue, reducing reagent residue, and an excess of the organic compound including a polyethylene oxide structure. The purification of the composite can be by reprecipitation, centrifugal sedimentation, or ultrafiltration, and such impurities can be washed away by cleaning the reaction mixture containing the finished composite with a cleaning solvent, such as water, ethanol, acetone, or a mixture thereof.

### <Production of the Electrically Conductive Paste for Forming Pillars>

The electrically conductive paste according to the present invention for forming pillars can be made suitable for use as an electrically conductive paste according to the present invention by adding a solvent easy to use as a filling paste to the resulting fine metal particles or carrying out or by exchanging media.

The electrically conductive paste according to the present invention for forming pillars may optionally contain added auxiliary ingredients unless the advantages of the present invention are impaired. Examples include resins or other binder components, agents that prevent the paste from drying, defemners, agents that make the paste adhesive to its substrate, antioxidants, catalysts for accelerating film formation, surfactants such as silicone or fluorinated surfactants, leveling agents, and release improvers.

The electrically conductive paste may contain an added flux component unless it impairs the advantages of the present invention. With an added flux component, the paste can also be used with extra reducing potential. The kind of flux is not critical; the flux can be a typical flux that is usually used. This flux may contain ingredients that are usually used, such as rosin, an activator, and a thixotropic agent.

### <Calculation of the Percentage of the Fine Metal Particles>

The percentage of the fine metal particles in the electrically conductive paste in the present invention can be calculated by thermogravimetry (TG/DTA). The electrically conductive paste was weighed precisely on an aluminum pan for thermogravimetry and set on a thermogravimetry and differential thermal analyzer. The temperature was increased from room temperature to 600° C. at a rate of 10° C. per minute in an inert gas atmosphere, and the percentage of the fine metal particles was calculated on the basis of the percentage weight loss.

### <Formation of Pillars>

The formation of pillars in the present invention can be by any method. For example, an easy and convenient method for forming pillars is to make them by spreading the electrically conductive paste to fill multiple openings in a substrate and sintering the paste.

Although it is not critical what kind of material is used as the substrate, materials such as metals, silicon, ceramic materials, resins, and composite materials formed thereby can be used. Making a resist film on such a substrate and creating openings by patterning gives a substrate having multiple openings. The resist film may be removed after the formation of the pillars, but may alternatively be left as a permanent film. The spread of the electrically conductive paste can be by any method. Methods such as a rubber squeegee, a doctor blade, a dispenser, inkjet printing, and press injection can be used.

Spreading the electrically conductive paste according to the present invention to fill the openings in the substrate and heating the paste to a temperature at which the fine metal particles fuse together gives pillars. If an easily oxidizable metal is used as a material, this can be done in hydrogen-containing forming gas, in a nitrogen atmosphere, c-r in an atmosphere of nitrogen containing formic acid prepared by passing forming acid through nitrogen.

The electrically conductive paste according to the present invention for forming pillars requires no applied pressure when sintered by heating. Simply spreading the paste to fill the openings and sintering the paste will make it deliver its full performance.

Alternatively, the electrically conductive paste can be pressed into the openings by applying the paste in an atmosphere at a reduced pressure of 0.9 to 0.01 atm (900 hPa to 1 hPa) and then return the system to atmospheric pressure.

For firing temperature, the fine metal particles fuse together if it is anywhere in the range of 150° C. to 350° C. For the duration of firing, the electrically conductive paste delivers its full performance if it is anywhere in the range of 1 to 60 minutes. To make the work quick and for the subsequent removal of the resist film, however, 5 to 15 minutes of firing at 250° C. or below is preferred. The electrically conductive paste according to the present invention delivers its full performance even if it is fired only for a short period of time.

If necessary, the electrically conductive paste according to the present invention may be fired using a temperature profile. For example, it may be calcined at low temperatures for solvent removal first and then fired in the range of 150° C. to 350° C.

Here, if the percentage of the fine metal particles in the electrically conductive paste is less than 40% concentration by mass, the amount of metallic component is so small that the fine metal particles do not fuse together when the paste is sintered in the openings. This causes the problem that the pillars not only fail to stand on their own after the peeling away of the resist but also have only insufficient electrical conductivity.

It is therefore preferred that the paste have a percentage of fine metal particles of at least 40% concentration by mass.

If the percentage of the fine metal particles in the electrically conductive paste exceeds 95% concentration by mass, the paste's high viscosity and high thixotropy make it difficult to fill high-aspect-ratio openings uniformly and tightly with the paste. It is also difficult to achieve a concave top surface of the pillars, which is a feature of the present invention.

It is therefore preferred that the percentage of the fine metal particles be 95% concentration by mass or less.

### EXAMPLES

The following describes the present invention in detail by examples. “%” is “% by mass” unless otherwise specified.

### [Measurement of Percentage Weight Loss by Thermogravimetry]

Two to twenty-five milligrams of the electrically conductive paste was weighed precisely on an aluminum pan for thermogravimetry and set on EXSTAR TG/DTA 6300 thermogravimetry and differential thermal analyzer (SII NanoTechnology Inc.). The temperature was increased from room temperature to 600° C. at a rate of 10° C. per minute in an inert gas atmosphere, and the percentage weight loss was measured between 100° C. and 600° C. The measured percentage weight loss was used to calculate the percentages of the fine metal particles and the protective agent.

### Example 1

A mixture of copper(II) acetate monohydrate (3.00 g, 15.0 mmol) (Tokyo Chemical Industry), ethyl 3-(3-(methoxy)polyethoxy)ethoxy)-2-hydroxypropylsulfanyl)propionate [adduct of polyethylene glycol methyl glycidyl ether (molecular weight of the polyethylene glycol chain, 2000 (91 carbon atoms)) with ethyl 3-mercaptopropionate] (0.451 g) (DIC), and ethylene glycol (10 mL) (Kanto Chemical) was degassed by 2 hours of stirring with aeration at 125° C. During this, the mixture was heated while nitrogen was blown thereinto at a flow rate of 50 mL/min. The mixture was allowed to cool back to room temperature, and a solution prepared by diluting hydrazine hydrate (1.50 g, 30.0 mmol) (Tokyo Chemical Industry) in 7 mL of water was slowly added dropwise using a syringe pump. Approximately ¼ the amount was slowly added dropwise over 2 hours, then the feeding of the solution was stopped, and the mixture was stirred for 2 hours. After the solution became flat, the rest was added dropwise over another 1 hour. The resulting brown solution was heated to 60° C. and stirred for another 2 hours to terminate the reduction.

### <Preparaticn of Water Dispersion>

Then this reaction mixture was circulated in Daicen Membrane-Systems' hollow-fiber ultrafiltration membrane module (HXT-1-FUS1592; 145 cm²; cutoff molecular weight, 150,000). The mixture was purified by circulation until approximately 500 mL of filtrate was collected from the ultrafiltration module while the leaching filtrate was compensated for with the same volume of a 0.1% aqueous solution of hydrazine hydrate. Stopping the supply of the 0.1% aqueous solution of hydrazine hydrate and continuing concentration by ultrafiltration gave a water dispersion of a composite of 2.85 g of a thioether-containing organic compound and fine particles of copper.

The fine particles of copper were observed under a transmission electron microscope (TEM), and the diameter of their primary particles was 20 nm. The non-volatile content of the water dispersion was 16% concentration by mass. A weight loss measured by TG-DTA indicated the fine particles of copper contained 3% organic substance including a polyethylene oxide structure.

### <Preparation of Electrically Conductive Paste>

Five milliliters of this water dispersion was each sealed in a 50-mL three-neck flask. While the flask was warmed to 40° C. in a water bath, nitrogen was passed at a flow rate of 5 ml/min under reduced pressure. This was continued until water was removed completely, yielding 1.0 g of a dry powder of the composite of fine particles of copper. Then, in a globe bag purged with argon gas, the dry powder was mixed with ethylene glycol in a mortar for 10 minutes to give an electrically conductive paste containing 80% concentration by mass fine metal particles. The ethylene glycol was bubbled with nitrogen for 30 minutes beforehand. A MEGAFACE fluorine leveling agent (DIC) was added to adjust the surface tension of the paste.

### Example 2

A 5.6-g quantity of copper nitrate (Tokyo Chemical Industry), 9.2 g of octylamine as a protective agent (Tokyo Chemical Industry), and 2.1 g of linoleic acid (Tokyo Chemical Industry) were added to 1 liter of trimethylpentane (Tokyo Chemical Industry) and mixed by stirring until they dissolved. To the resulting mixture solution, 1 liter of a solution of 0.01 moles/liter sodium borohydride (Tokyo Chemical Industry) in propanol (Tokyo Chemical Industry) was added dropwise over 1 hour to reduce copper. The mixture was then stirred for 3 hours to give a black liquid. The resulting black liquid was concentrated with an evaporator, and then 2 liters of methanol was added to the residue. A brown precipitate formed, and this precipitate was collected by suction filtration. The precipitate formed was again dispersed in trimethylpentane, and the dispersion was filtered. The residue was dried to give fine particles of copper as a black solid. The fine particles of copper were observed under a transmission electron microscope (TEM), and the diameter of their primary particles was 6 nm. Then based on a weight loss measured by TG-DTA, it was found that the fine particles of copper contained 15% organic substance.

Then, in a globe bag purged with argon gas, 1.0 g of the dry powder of fine particles of copper was mixed with terpineol (Wako Pure Chemical Industries) in a mortar for 10 minutes to give an electrically conductive paste containing 80% concentration by mass fine metal particles. The terpineol was bubbled with nitrogen for 30 minutes beforehand. A MEGAFACE fluorine leveling agent (DIC) was added to adjust the surface tension of the paste.

### Example 3

In an argon gas atmosphere, 153.2 g (1.738 mol) of N,N-dimethylethylenediamine (Tokyo Chemical Industry) and 325.6 g (1.738 mol) of 3-(2-ethylhexyloxy)propylamine were added to a 1-L flask. The resulting liquid mixture was heated with stirring in an oil bath until its internal temperature was 30° C. With continued heating and stirring, 35.2 g (0.116 mol) of silver oxalate was added, and the resulting mixture was heated with stirring until its internal temperature was 40° C. After heating and stirring continued for 1 hour, the temperature of the oil bath was increased to 95° C. with the top of the flask open. The temperature of the reaction solution rose to 90° C. to 97° C. because of thermal decomposition of the silver oxalate and amines. Then the flask was removed from the oil bath and allowed to cool in an argon gas atmosphere until the internal temperature of the reaction solution was 40° C. or below, yielding a dispersion of fine particles of silver.

### (Decantaticn of the Dispersion of Fine Particles of Silver)

To remove an excess of amines from the dispersion of fine particles of silver, the dispersion of fine particles of silver was cleaned by decantaticn with N-hexane (Kanto Chemical). After the decantation, approximately 22 g of a dispersion of fine particles of silver was obtained.

### (Redispersion of the Dispersion of Fine Particles of Silver)

To the resulting dispersion of fine particles of silver, a liquid mixture of 1-butanol (Kanto Chemical) with ricinoleic acid (Tokyo Chemical Industry) was added to make the silver concentration 80% by mass. The ricinoleic acid was added to make up 2.0% concentration by mass of the silver in the dispersion. The resulting mixture was stirred for approximately 0.5 hours to give a brown electrically conductive paste. A MEGAFACE fluorine leveling agent (DIC) was added to adjust the surface tension of the paste.

The fine particles of copper were observed under a transmission electron microscope (TEM), and the diameter of their primary particles was 17 nm. Then based on a weight loss measured by TG-D7A, it was found that the fine particles of silver contained 7% concentration by mass organic substance.

Table 1 is a summary of test results for electrically conductive pastes produced as in Examples 1 to 3 filled into a pattern having openings.

The shape of the openings is cylindrical. The diameters are 100, 50, 40, 30, and 20 μm, and the depth of the openings is 56 μm. The aspect ratios are therefore 0.6, 1.1, 1.4, 1.9, and 2.8, respectively. The pattern was designed so that holes:space=1:1.

In these Examples, the filling with the paste was carried out using a rubber squeegee for screen printing. The paste was spread to fill the openings using a rubber squeegee and then was sintered at 250° C. for 10 minutes in an inert gas atmosphere.

The surface condition of the sintered film was graded by observation under optical and laser microscopes.

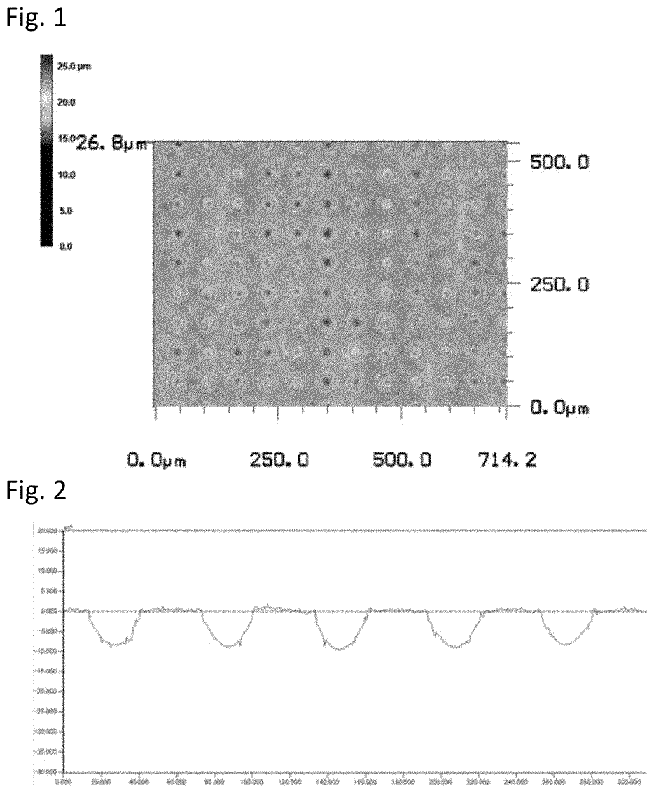

FIG. 1 illustrates the geometry of the surface of the resist after the electrically conductive paste was spread to fill openings having a diameter of 30 μm and sintered. The electrically conductive paste used was that described in Example 1. The observation revealed the electrically conductive paste filled all openings uniformly.

FIG. 2 illustrates a cross-sectional profile after the electrically conductive paste was spread to fill openings having a diameter of 30 μm and sintered. The 0-μm point on the vertical axis, indicated by a broken line, represents the surface of the resist. This figure revealed that the filling electrically conductive paste has a concave top. The center of the concave portion was approximately 10 μm below the surface.

For grading criteria,

└: Represents a state in which the electrically conductive paste filled 90 or more in 100 opening patterns i.e., a yield of 90% or more;

O: Represents a state in which the electrically conductive paste filled 70 or more in 100 opening patterns i.e., a yield of 70% or more;

Δ: Represents a state in which the electrically conductive paste filled 50 or more in 100 opening patterns i.e., a yield of 50% or more; and

x: Represents a state in which the electrically conductive paste filled less than 50 in 100 opening patterns, i.e., a yield of less than 50%.

TABLE 1

| | | Example 1 | Example 2 | Example 3 |
|---|---|---|---|---|
| Percentage of fine metal particles | | 80% | 80% | 80% |
| Diameter of | 100 μm | ⊙ | ⊙ | ⊙ |
| pillars | 50 μm | ⊙ | ⊙ | ⊙ |
| | 40 μm | ⊙ | ⊙ | ⊙ |
| | 30 μm | ⊙ | ⊙ | ⊙ |
| | 20 μm | ⊙ | ⊙ | ⊙ |

These results indicate that electrically conductive pillars can be made without being restricted to the kind of protective agent and metal species. Similar pillars, moreover, can be formed even in a very small diameter of 20 μm without being restricted to the diameter of the openings.

### Example 4

An electrically conductive paste containing 90% concentration by mass fine metal particles was produced by mixing a dry powder of a composite of fine particles of copper prepared as in Example I with ethylene glycol in a mortar for 10 minutes in a globe bag purged with argon gas. The ethylene glycol was bubbled with nitrogen for 30 minutes beforehand.

### Example 5

An electrically conductive paste containing 70% concentration by mass fine metal particles was produced by mixing a dry powder of a composite of fine particles of copper prepared as in Example 1 with ethylene glycol in a mortar for 10 minutes in a globe bag purged with argon gas. The ethylene glycol was bubbled with nitrogen for 30 minutes beforehand.

### Example 6

An electrically conductive paste containing 40% concentration by mass fine metal particles was produced by mixing a dry powder of a composite of fin(c) particles of copper prepared as in Example 1 with ethylene glycol in a mortar for 10 minutes in a globe bag purged with argon gas. The ethylene glycol was bubbled with nitrogen for 30 minutes beforehand.

### Comparative Example 1

An electrically conductive paste containing 20% concentration by mass fine metal particles was produced by mixing a dry powder of a composite of fine particles of copper prepared as in Example 1 with ethylene glycol in a mortar for 10 minutes in a globe bag purged with argon gas. The ethylene glycol was bubbled with nitrogen for 30 minutes beforehand.

### Comparative Example 2

An electrically conductive paste containing 95% concentration by mass fine metal particles was produced by mixing a dry powder of a composite of fine particles of copper prepared as in Example 1 with ethylene glycol in a mortar for 10 minutes in a globe bag purged with argon gas. The ethylene glycol was bubbled with nitrogen for 30 minutes beforehand.

Table 2 is a summary of test results for electrically conductive pastes produced as in Examples 4 to 6 and Comparative Examples 1 and 2 filled into a pattern having openings.

The shape of the openings is cylindrical. The diameters are 100, 50, 40, 30, and 20 μm, and the depth of the openings is 56 μm. The aspect ratios are therefore 0.6, 1.1, 1.4, 1.9, and 2.8, respectively. The pattern was designed so that holes:space=1:1.

In these Examples, the filling with the paste was carried out using a rubber squeegee for screen printing. The paste was spread to fill the openings using a rubber squeegee and then was sintered at 250° C. for 10 minutes in an inert gas atmosphere.

The surface condition of the sintered film was graded by observation under optical and laser microscopes.

For grading criteria,

⊙: Represents a state in which the electrically conductive paste filled 90 or more in 100 opening patterns, i.e., a yield of 90% or more;

O: Represents a state in which the electrically conductive paste filled 70 or more in 100 opening patterns, i.e., a yield of 70% or more;

Δ: Represents a state in which the electrically conductive paste filled 50 or more in 100 opening patterns, i.e., a yield of 50% or more; and

x: Represents a state in which the electrically conductive paste filled less than 50 in 100 opening patterns, i.e., a yield of less than 50%.

TABLE 2

| | | | | | Comparative | Comparative |
|---|---|---|---|---|---|---|
| | | Example 4 | Example 5 | Example 6 | Example 1 | Example 2 |
| Percentage of fine | | 90% | 70% | 40% | 20% | 95% |
| metal particles | | | | | | |
| Diameter of | 100 μm | ⊙ | ⊙ | ◯ | X | Δ |
| pillars | 50 μm | ⊙ | ◯ | ◯ | X | X |
| | 40 μm | ⊙ | ◯ | Δ | X | X |
| | 30 μm | ⊙ | ◯ | Δ | X | X |
| | 20 μm | ⊙ | ◯ | Δ | X | X |

These results indicate that electrically conductive pillars can be made in any diameter as long as the percentage of the fine metal particles is in the range of 40% or more to less than 95% concentration by mass.

It was revealed that if the percentage of the fine metal particles is less than 40% (e.g., Comparative Example 1), electrically conductive pillars cannot be formed after sintering because of the low metal content.

If the percentage of the fine metal particles is 95% or more (e.g., Comparative Example 2), by contrast, the paste is highly viscous and does not flow smoothly. It was revealed that because of this, the electrically conductive paste does not fill the openings if spread using a rubber squeegee.

1. An electrically conductive paste for forming pillars, the paste comprising:
fine metal particles: and
a protective agent, wherein
a diameter of the fine metal particles is less than 1 μm, and a percentage of the fine metal particles in the electrically conductive paste is 40% or more and less than 95% concentration by mass.

2. The electrically conductive paste according to claim 1 for forming pillars, the paste further comprising a solvent having a boiling point of 250° C. or less.

3. The electrically conductive paste according to claim 1 for forming pillars, wherein the protective agent contains an organic compound including a C8 to C200 polyethylene oxide structure.

4. The electrically conductive paste according to claim 3 for forming pillars, wherein a percentage of the organic compound including a C8 to C200 polyethylene oxide structure is 15% concentration by mass or less of the entire paste.

5. The electrically conductive paste according to claim 1 for forming pillars, wherein the fine metal particle are particles of silver, copper, or a composite thereof.

6. A pillar made using the electrically conductive paste according to claim 1 for forming pillars.
